(19) United States
(12) Patent Application Publication
(10) Pub. No.: US 2023/0209920 A1
(43) Pub. Date: Jun. 29, 2023

(54) DISPLAY PANEL AND DISPLAY DEVICE INCLUDING THE SAME

(71) Applicant: LG Display Co., Ltd., Seoul (KR)

(72) Inventors: Je Hyung PARK, Paju-si (KR); Da Yeong LEE, Paju-si (KR)

(73) Assignee: LG Display Co., Ltd., Seoul (KR)

(21) Appl. No.: 17/975,379

(22) Filed: Oct. 27, 2022

(30) Foreign Application Priority Data
Dec. 28, 2021 (KR) 10-2021-0190429

(51) Int. Cl. H01L 27/32

(52) U.S. Cl. CPC H01L 27/3272; H01L 27/323; H01L 27/3276

(57) ABSTRACT

A display panel can include a display area having a curved line at at least a portion thereof, and a non-display area adjacent to the display area. The display panel can include a first pixel included in the display area, and a second pixel disposed at a position corresponding to the curved line in the display area. A light shielding member can be disposed on the second pixel and can be disposed to correspond to the position of the second pixel.

### CROSS-REFERENCE TO RELATED APPLICATION

This application claims priority to Korean Patent Application No. 10-2021-0190429 filed in the Republic of Korea on Dec. 28, 2021, the entire contents of which are hereby expressly incorporated by reference into the present application.

### BACKGROUND

### Field

The disclosure relates to a display panel having a curved line shape at at least a portion thereof and a display device including such display panel.

### Discussion of the Related Art

As a display device used in a monitor of a computer, a TV, a portable phone, or the like, there exist an organic light emitting display device (OLED) configured to self-luminously emit light, a liquid crystal display device (LCD) requiring a separate light source, etc.

The application range of such a display device is diverse. For example, the display device is applicable not only to a monitor of a computer and a TV, but also to a personal portable appliance. Accordingly, the display device can be implemented to have not only a quadrangular shape, which is mainly used in conventional cases, but can have also various shapes different from the quadrangular shape. Such a shape can be referred to as a “hetero-shape” and an oval shape can be an example of such a shape.

When the display device is implemented to have a hetero-shape, at least a portion of a display area in which content is displayed can have a curved line shape. However, pixels (or picture elements), which are included in the display area and emit light, for display of content, have a quadrangular shape. In this case, the portion of the display area having the curved line shape can appear in the form of a staircase (or a step) and, as such, degradation in display quality can occur.

### SUMMARY OF THE DISCLOSURE

Accordingly, the disclosure is directed to a display panel and a display device including the same that substantially obviate one or more problems due to limitations and disadvantages of the related art.

An object of the disclosure is to provide a display panel in which a light shielding member is disposed on a pixel disposed in a curved line portion of a display area, to control a light emission amount of the pixel, thereby achieving an enhancement in display quality, and is to provide a display device including such display panel.

Additional advantages, objects, and features of the exemplary embodiments of the disclosure will be set forth in part in the description which follows and in part will become apparent to those having ordinary skill in the art upon examination of the following or can be learned from practice of the exemplary embodiments of the disclosure. The objectives and other advantages of the exemplary embodiments of the disclosure can be realized and attained by the structure particularly pointed out in the written description and claims hereof as well as the appended drawings.

To achieve these objects and other advantages and in accordance with the purpose of the exemplary embodiments of the disclosure, as embodied and broadly described herein, a display panel includes a display area shaped into a curved line at at least a portion thereof, a non-display area adjacent to the display area, a first pixel included in the display area, a second pixel disposed at a position corresponding to the curved line in the display area, and a light shielding member disposed on the second pixel and disposed to correspond to the position of the second pixel.

In another aspect of the disclosure, there is provided a display device including a display panel including a display area having a curved line at at least a portion thereof, and a non-display area adjacent to the display area, and a driving circuit configured to drive the display panel, wherein the display panel includes a first pixel included in the display area, and a second pixel disposed at a position corresponding to the curved line in the display area. Further, a light shielding member is disposed on the second pixel and disposed to correspond to the position of the second pixel.

The effects of the embodiments disclosed in the disclosure are not limited to the above-described effects, and other effects which are not described herein can be derived by those skilled in the art from the following description of the embodiments of the disclosure.

### BRIEF DESCRIPTION OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a block diagram of an example of a display device according to an exemplary embodiment of the disclosure;

FIG. 2 is a diagram illustratively showing an equivalent circuit of a sub-pixel of a display device according to an exemplary embodiment of the disclosure;

FIG. 3 is a view explaining a curved line portion in a display device according to an exemplary embodiment of the disclosure;

FIG. 4 is a view explaining pixels of a display device according to an exemplary embodiment of the disclosure;

FIGS. 5 and 6 are views explaining cross-sections of a display device according to an exemplary embodiment of the disclosure;

FIG. 7 is a view explaining a pixel of a display device according to another exemplary embodiment of the disclosure;

FIGS. 8 and 9 are views explaining cross-sections of display devices according to different exemplary embodiments of the disclosure, respectively; and

FIGS. 10 to 13 are views explaining a structure for realizing a touch function of a display device according to an exemplary embodiment of the disclosure.

### DETAILED DESCRIPTION OF THE EMBODIMENTS

Most of the terms used herein are general terms that have been widely used in the technical art to which one or more exemplary embodiments pertain. However, some of the terms used herein can be created to reflect the intentions of technicians in this art, precedents, or new technologies. Also, some of the terms used herein can be arbitrarily chosen by the inventor. In this case, these terms are defined in detail below. Accordingly, the specific terms used herein should be understood based on the unique meanings thereof and the whole context of one or more exemplary embodiments.

When “comprise”, “have”, and “include” described in the specification are used, another part can be added unless “only˜” is used.

An expression “at least one of a, b or c” used in the disclosure can include “a alone”, “b alone”, “c alone”, “a and b”, “a and c”, “b and c” or “all of a, b and c”. Advantages and features of the exemplary embodiments of the disclosure and a method for accomplishing the advantages and features will be apparent upon referring to the following exemplary embodiments of the disclosure described in detail with reference to the accompanying drawings.

A shape, a size, a ratio, an angle, and a number disclosed in the drawings for describing embodiments of the disclosure are merely an example, and thus, the disclosure is not limited to the illustrated details. In the following description, when the detailed description of the relevant known function or configuration is determined to unnecessarily obscure the gist of the disclosure, the detailed description will be omitted.

When “comprise”, “have”, and “include” described in the specification are used, another part can be added unless “only˜” is used. Terms in a singular form can include plural forms unless stated otherwise. In construing an element, the element is construed as including a tolerance range, even if there is no explicit description.

In describing a positional relationship between two elements, for example, when the positional relationship is described using “upon˜”, “above˜”, “below˜”, and “next to˜”, one or more other elements can be interposed between the two elements unless “just” or “directly” is used.

It will be understood that, although the terms “first”, “second”, etc. can be used herein to describe various elements, these elements should not be limited by these terms. These terms are only used to distinguish one element from another and may not define order. For example, a first element referred to in the following description can represent a second element, without departing from the scope of the disclosure.

Areas, lengths or thicknesses of constituent elements disclosed in the disclosure can be exaggeratedly illustrated for clarity and convenience of explanation. Thus, the exemplary embodiments of the disclosure are not limited to the illustrated details.

Features of the exemplary embodiments of the disclosure can be partially or overall coupled or combined, and can be technically linked and implemented in various manners. The embodiments can be independently implemented, or can be implemented in an association relationship.

Further, the following terms are defined in consideration of the functions of the exemplary embodiments of the disclosure and can be construed in different ways by intention or practice of users and operators. Therefore, the definitions of terms used in the disclosure should be construed based on the contents of the disclosure.

A transistor constituting a pixel circuit of the disclosure can include at least one of an oxide thin film transistor (oxide TFT), an amorphous silicon TFT (a-Si TFT), or a low-temperature polysilicon (LTPS) TFT.

The following embodiments will be described mainly in conjunction with an organic light emitting display device. However, the embodiments of the disclosure are not limited to the organic light emitting display device, and can also be applied to an inorganic light emitting display device including an inorganic luminescent material. For example, the embodiments of the disclosure can also be applied to a quantum dot display device. Further, all components of each display device according to all embodiments of the disclosure are operatively coupled and configured.

Expressions such as “first”, “second” and “third” are terms used to distinguish configurations from one another in accordance with different embodiments. Of course, the embodiments of the disclosure are not limited to such terms. In this regard, it is noted that, although the same term is used in different embodiments, the term can represent different configurations in accordance with the embodiments.

Hereinafter, the exemplary embodiments of the disclosure will be described with reference to the accompanying drawings.

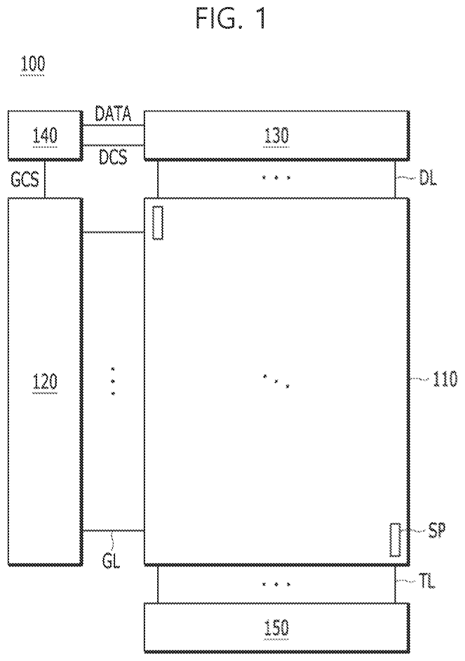

FIG. 1 is a block diagram of an example of a display device according to an exemplary embodiment of the disclosure.

Referring to FIG. 1, a display device 100 according to an exemplary embodiment of the disclosure, which can be, for example, a touch display device, can include a display panel 110, a gate driving circuit 120, a data driving circuit 130, a timing controller 140, and a touch driving circuit 150 configured to sense touches on the display panel 110.

A plurality of gate lines GL and a plurality of data lines DL are disposed at the display panel 110, and a plurality of sub-pixels SP can be disposed in areas where the gate lines GL and the data lines DL intersect each other.

In addition, a plurality of touch electrodes can be disposed on or built in the display panel 110, and a plurality of touch lines TL, which electrically interconnect the touch electrodes and the touch driving circuit 150, can be disposed at the display panel 110.

A configuration for display driving in the display device 100 will be first described. The gate driving circuit 120 controls driving timing of the sub-pixel SP disposed at the display panel 110. In addition, the data driving circuit 130 supplies a data voltage corresponding to image data to the sub-pixel SP. As a result, the sub-pixel SP emits light at a brightness corresponding to the grayscale of the image data and, as such, displays an image.

In detail, the gate driving circuit 120 is controlled by the timing controller 140, and sequentially outputs a scan signal to the plurality of gate lines GL disposed at the display panel 110, thereby controlling driving timing of the plurality of sub-pixels SP.

The gate driving circuit 120 can include one or more gate driving integrated circuits (GDICs), and can be disposed at only one side of the display panel 110 or at both sides of the display panel 110. Alternatively, the gate driving circuit 120 can be directly built in a bezel area of the display panel 110 and, as such, can be implemented in a gate-in-panel (GIP) type.

The data driving circuit 130 receives image data DATA having a digital form from the timing controller 140, and converts the image data DATA into a data voltage having an analog form. In addition, the data driving circuit 130 outputs data voltages to the data lines DL in accordance with timing of application of scan signals via the gate lines GL, respectively, thereby enabling the sub-pixels SP to represent brightness values according to the data voltages, respectively.

The data driving circuit 130 can include one or more source driving integrated circuits (SDICs).

The timing controller 140 supplies various control signals to the gate driving circuit 120 and the data driving circuit 130 and, as such, controls operations of the gate driving circuit 120 and the data driving circuit 130.

The timing controller 140 controls the gate driving circuit 120 to output a scan signal in accordance with timing implemented in each frame, converts image data DATA received from an exterior so that the image data is suitable for a data signal format used in the data driving circuit 130, and outputs the converted image data DATA to the data driving circuit 130.

The timing controller 140 receives, from the exterior (for example, a host system), various timing signals including a vertical synchronization signal, a horizontal synchronization signal, an input data enable signal, a clock signal, etc., together with the image data DATA.

The timing controller 140 can generate a data control signal DCS and a gate control signal GCS using the various timing signals received from the exterior, and can output the data control signal DCS and the gate control signal GCS to the data driving circuit 130 and the gate driving circuit 120, respectively.

For example, the timing controller 140 can output various gate control signals GCS including a gate start pulse, a gate shift clock, a gate output enable signal, etc. in order to control the gate driving circuit 120.

Here, the gate start pulse controls operation start timing of one or more gate driving integrated circuits constituting the gate driving circuit 120. The gate shift clock is a clock signal input n common to the one or more gate driving integrated circuits, and controls shift timing of a scan signal. The gate output enable signal designates timing information of the one or more gate driving integrated circuits.

In addition, the timing controller 140 outputs various data control signals DCS including a source start pulse, a source sampling clock, a source output enable signal, etc. in order to control the data driving circuit 130.

Here, the source start pulse controls data sampling start timing of one or more source driving integrated circuits constituting the data driving circuit 130. The source sampling clock is a clock signal for controlling sampling timing of data in each source driving integrated circuit. The source output enabling signal controls output timing of the data driving circuit 130.

The display device 100 as described above can further include a power management integrated circuit configured to supply various voltages or currents to the display panel 110, the gate driving circuit 120, the data driving circuit 130, the touch driving circuit 150, etc., or to control the various voltages or currents to be supplied.

Meanwhile, when an encapsulation layer is formed on the display panel 110, and a touch electrode is disposed on the encapsulation layer, the capacitance for driving of the touch electrode can increase. In this case, it can be necessary to increase the level of a touch driving signal for driving of the touch electrode. To this end, a level shifter can be added between the touch driving circuit 150 and the display panel 110 to control the level of the touch driving signal.

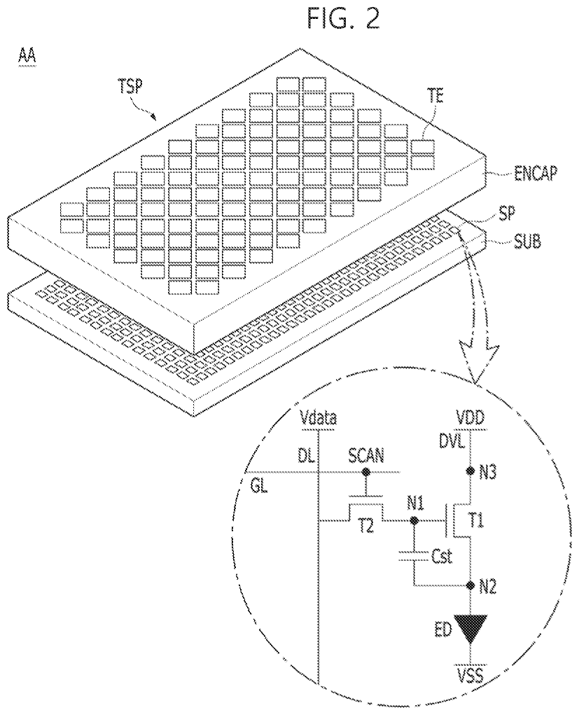

FIG. 2 is a diagram illustratively showing an equivalent circuit of a sub-pixel of a display device according to an exemplary embodiment of the disclosure.

Referring to FIG. 2, in a display device 100 according to an exemplary embodiment of the disclosure, a plurality of sub-pixels SP is arranged on a substrate SUB in a display area. AA of a display panel 110.

Each sub-pixel SP can include a light emitting element ED, a first transistor T1 for driving the light emitting element ED, a second transistor T2 for transmitting a data voltage Vdata to a first node N1 of the first transistor T1, a storage capacitor Cst for maintaining a constant voltage for one frame, etc.

The first transistor T1 can include the first node N1, to which the data voltage Vdata is applicable via the second transistor T2, a second node N2 electrically connected to the light emitting element ED, and a third node N3, to which a driving voltage VDD is applied from a driving voltage line DVL. The first node N1 is a gate node, the second node N2 can be a source node or a drain node, and the third node N3 can be a drain node or a source node. The first transistor T1 as described above can be referred to as a driving transistor for driving the light emitting element ED.

The light emitting element ED can include a first electrode (for example, an anode), a light emitting layer, and a second electrode (for example, a cathode). The first electrode can be electrically connected to the second node N2 of the first transistor T1, and a ground voltage VSS can be applied to the second electrode.

In the light emitting element ED as described above, the light emitting layer can be an organic light emitting layer including an organic material. In this case, the light emitting element ED can be an organic light emitting diode.

Turning-on/off of the second transistor T2 can be controlled by a scan signal SCAN applied to the second transistor T2 via a gate line GL, and the second transistor T2 can be electrically connected between the first node N1 of the first transistor T1 and a data line DL. The second transistor T2 as described above can be referred to as a switching transistor.

When the second transistor T2 is turned on by the scan signal SCAN, the data voltage Vdata supplied thereto via the data line DL is transmitted to the first node N1 of the first transistor T1.

The storage capacitor Cst can be electrically connected between the first node N1 and the second node N2 of the first transistor T1.

Each sub-pixel SP can have a 2T1C structure including two transistors T1 and T2 and one capacitor Cst. If necessary, each sub-pixel SP can further include one or more transistors, or can further include one or more capacitors.

The storage capacitor Cst may not be a parasitic capacitor, which can be present between the first node N1 and the second node N2 of the first transistor T1, but can be an external capacitor intentionally designed at an exterior of the first transistor T1.

Each of the first transistor T1 and the second transistor T2 can be an n-type or p-type transistor.

In addition, each of the first transistor and the second transistor 12 can be constituted by a low-temperature polysilicon transistor. Of course, the exemplary embodiments of the disclosure are not limited to the above-described condition, and at least one of the first transistor T1 and the second transistor T2 can be constituted by an oxide thin film transistor.

Meanwhile, a circuit element such as one light emitting element ED, two or more transistors T1 and T2, one or more capacitors Cst, etc. is provided. Since such a circuit element is weak against ambient moisture, oxygen or the like, an encapsulation layer ENCAP can be disposed on the display panel 110 in order to prevent ambient moisture or oxygen from penetrating the circuit element.

In the display device 100 according to the exemplary embodiment of the disclosure, a touchscreen panel TSP can be formed on the encapsulation layer ENCAP and, as such, can be built in the display panel 110, For example, in the display device 100, a plurality of touch electrodes TE constituting the touchscreen panel TSP can be disposed on the encapsulation layer ENCAP, thereby constituting the display panel 110.

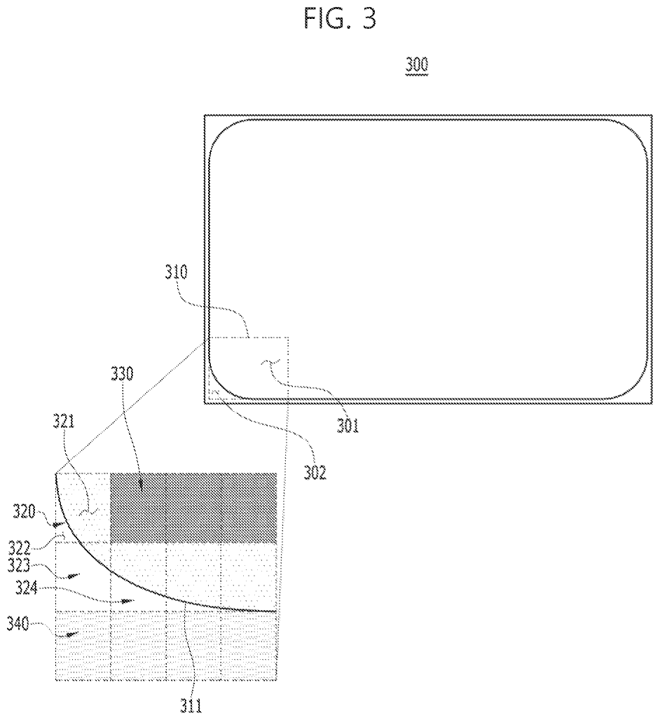

FIG. 3 is a view explaining a curved line portion in a display device according to an exemplary embodiment of the disclosure.

Referring to FIG. 3, a display device 300 can include a hetero-shaped display panel. For example, the display device 300 may not include a quadrangular display panel mainly used in conventional cases, but can include a hetero-shaped display panel having a curved line portion at at least a portion of a periphery thereof. For example, a periphery (or a boundary) of a display area 301 can appear in the form of a curved line, as in a first area 310 of the display device 300. A non-display area 302 can be disposed outside the display area 301.

In an embodiment, the display area 301 of the display device 300 can correspond to an oval shape or a circular shape. In this case, at least a portion of the display area 301 can appear in the form of a curved line.

The display area 301 includes an area in which content is displayed. The display area 301 can include a plurality of pixels (or light emitting elements) for display of content. The pixels can have a quadrangular shape. In this case, a part of the pixels included in the display device 300 (for example, a first pixel 330) can be disposed so that the entirety thereof is included in the display area 301, whereas the remaining part of the pixels (for example, a second pixel 320) can be disposed so that a portion thereof is included in the display area 301.

For example, the entirety of the first pixel 330 can be disposed in the display area 301. In the case of the second pixel 320, a first portion 321 can be disposed in the display area 301, and a second portion 322 can be disposed in a non-display area 302.

Since the first pixel 330 is completely included in the display area 301, the first pixel 330 can emit light in a 100% emission state. For example, the first pixel 330 can emit light in an emission amount equal to a light emission amount realized in accordance with the function of the first pixel 330.

The second pixel 320 can be a pixel disposed at a position corresponding to a curved line 311 of the display area 301. For example, the second pixel 320 can include a pixel disposed on the curved line 311. For another example, the second pixel 320 can include a pixel overlapping with the curved line 311.

In an embodiment, a light shielding member can be disposed on the second pixel 320 and, as such, the light emission amount of the second pixel 320 can be controlled. For example, when a light shielding member corresponding to a first area is disposed on the second pixel 320, the light emission amount of the second pixel 320 can be controlled in accordance with the area of the light shielding member. In a more concrete example, when a light shielding member corresponding to 20% of the area of the second pixel 320 is disposed on the second pixel 320, the second pixel 320 can emit light in an emission state corresponding to an area not shielded by the light shielding member, for example, an 80% emission state. The second pixel 320 can emit light in a light emission amount corresponding to 80% of a light emission amount realized in accordance with a function of the first pixel 330.

In an embodiment, the light shielding member can correspond to the position of the second pixel 320. For example, the area and disposition of the light shielding member can be predetermined in accordance with the position of the second pixel 320. For example, when the position of the second pixel 320 is a position at which about 50% of the second pixel 320 is included in the non-display area 302, the light shielding member can be disposed to overlap with the second pixel 320 (or a sub-pixel included in the second pixel 320). In addition, the light shielding member can have an area covering 50% of a light emission region of the second pixel 320 corresponding to a non-display area rate of the light shield member.

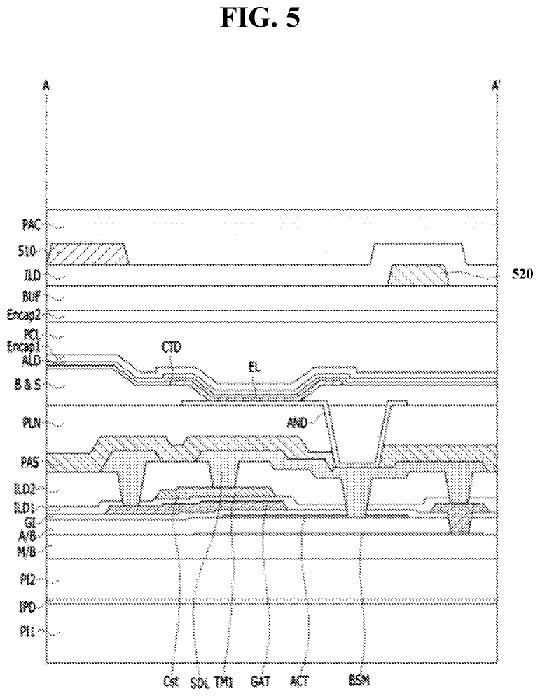

In an embodiment, the ratio of the area of the light shielding member to the area of the light emission region (or the light emitting layer) of a pixel (or a sub-pixel), at which the light shielding member is disposed, can correspond to the ratio of the area of the second portion 322 to the area of the second pixel 320. Here, the light emission region can correspond to a light emitting layer EL, which will be described later with reference to FIG. 5, without being limited thereto. In accordance with an embodiment, the light emission region can correspond to the entire light emission region including a cathode CTD, an anode AND and a light emitting layer EL.

In an embodiment, in the pixel disposed on the curved line 311, the area of a portion thereof included in the display area 301 (for example, the first portion 321) and the area of a portion thereof included in the non-display area 302 (for example, the second portion 322) can be varied in accordance with the position of the pixel on the curved line 311. For example, in the second pixel 320, the areas of the first portion 321 and the second portion 322 can be predetermined in accordance with the position of the second pixel 320 on the curved line 311 and, as such, the area of the light shielding member can be predetermined.

For example, other pixels disposed on the curved line 311, for example, a third pixel 323 and a fourth pixel 324, have positions different from that of the second pixel 320 and, as such, the area of a light shielding member disposed at each of the third pixel 323 and the fourth pixel 324 can be different from that of the light shielding member disposed at the second pixel 320. Of course, the exemplary embodiments of the disclosure are not limited to the above-described condition, and two pixels respectively disposed on the curved line 311 at different positions can have the same light shielding member area in accordance with areas thereof included in the display area 301 and/or the non-display area 302.

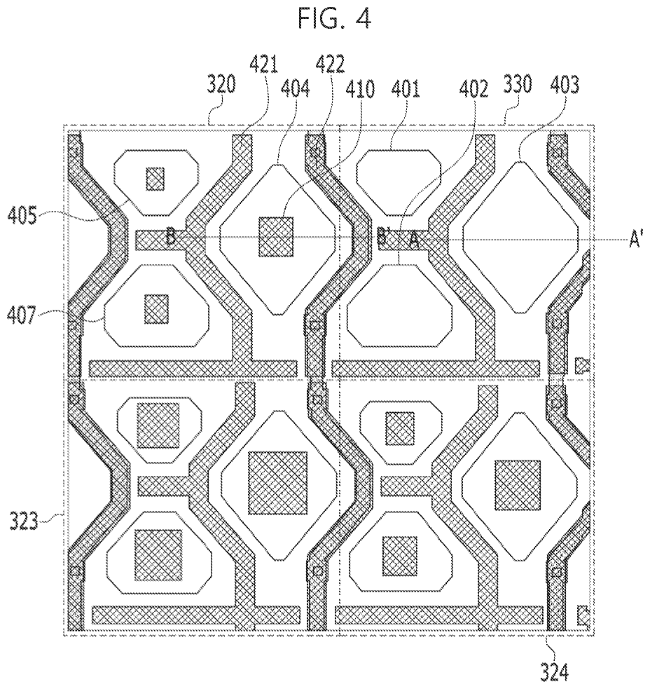

A more concrete example of the first pixel 330, the second pixel 320, the third pixel 323 and the fourth pixel 324 will be described later with reference to FIG. 4.

In an embodiment, a dummy pixel 340 can be disposed in the non-display area 302. The dummy pixel 340 can be a pixel not emitting light. The entirety of the dummy pixel 340 can be included in the non-display area 302.

If necessary, disposition of the dummy pixel 340 in the non-display area 302 can be omitted. In this case, a configuration needed for driving of the display device 300, such as a wiring connected to a pixel or the like can be disposed in the non-display area 302.

Meanwhile, although the light shielding member has been described in this exemplary embodiment as being disposed on the pixel, light shielding members can be disposed on a plurality of sub-pixels, respectively, when the pixel is implemented to include the plurality of sub-pixels. In addition, in this case, areas of the light shielding members can be determined based on ratios thereof to areas of the plurality of sub-pixels. For example, when the pixel is included in the non-display area in a rate of 30%, each light shielding member can be provided to cover 30% of each of the plurality of sub-pixels.

FIG. 4 is a view explaining pixels of a display device according to an exemplary embodiment of the disclosure. In detail, FIG. 4 concretely shows the first pixel 330 to the fourth pixel 324 of FIG. 3.

Referring to FIG. 4, in the first pixel 330, disposition of a light shielding member can be omitted because the entirety of the first pixel 330 is included in the display area. In detail, the first pixel 330 can include a first sub-pixel 401, a second sub-pixel 402, and a third sub-pixel 403.

The first sub-pixel 401 can emit red light, the second sub-pixel 402 can emit green light, and the third sub-pixel 403 can emit blue light. Light emission regions of the first sub-pixel 401, the second sub-pixel 402 and the third sub-pixel 403 can correspond to shapes of the first sub-pixel 401, the second sub-pixel 402 and the third sub-pixel 403 shown in FIG. 4, respectively. In this case, no light shielding member can be disposed on light emission regions of the first sub-pixel 401, the second sub-pixel 402 and the third sub-pixel 403.

If necessary, a pixel or sub-pixel configured to emit white light can be added to a pixel (for example, the first pixel 330 or the second pixel 320), at least one sub-pixel can be omitted from the pixel, or at least one sub-pixel of the pixel can emit light of a different color.

In an embodiment, in the second pixel 320, a portion thereof corresponding to 80% of the entirety of the second pixel 320 can be included in the display area, and a portion thereof corresponding to 20% of the entirety of the second pixel 320 can be included in the non-display area. In this case, a light shielding member corresponding to 20% of the area of a light emission region of the second pixel 320 can be disposed on the light emission region of the second pixel 320.

This will be descried in detail. The second pixel 320 can include a plurality of sub-pixels constituting the second pixel 320. For example, the plurality of sub-pixels constituting the second pixel 320 can include a first sub-pixel 405, a second sub-pixel 407, and a third sub-pixel 404. In this case, the first sub-pixel 405 can emit red light, the second sub-pixel 407 can emit green light, and the third sub-pixel 404 can emit blue light, without being limited thereto.

Light emission regions of sub-pixels can correspond to shapes of the sub-pixels shown in FIG. 4, respectively. A light shielding member can be disposed on the light emission region of a sub-pixel. For example, as shown in FIG. 4, a light shielding member 410 can be disposed on the light emission region of the third sub-pixel 404. The area of the light shielding member 410 can correspond to the area of the second pixel 320 included in the non-display area. For example, when the area of the second pixel 320 included in the non-display area corresponds to 20% of the total area of the second pixel 320, the area of the light shielding member 410 disposed on the third sub-pixel 404 can correspond to 20% of the area of the light emission region of the third sub-pixel 404.

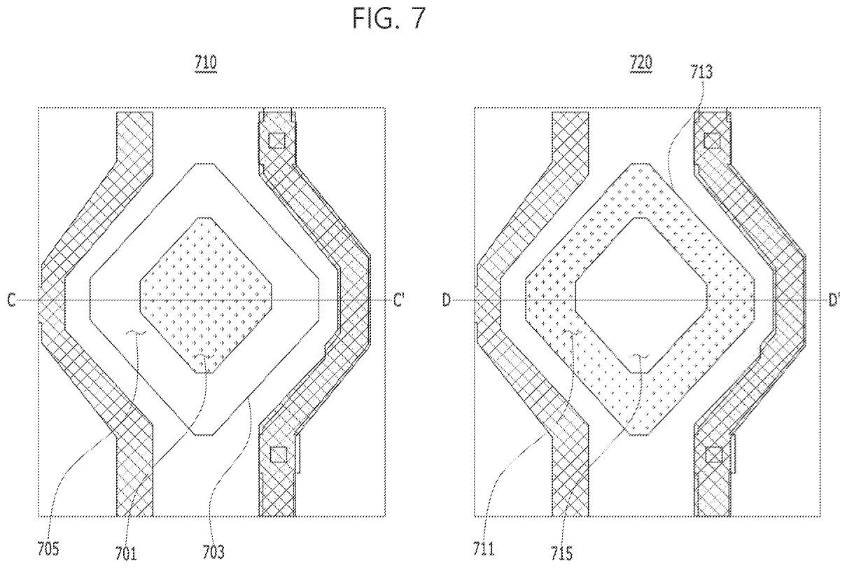

In an embodiment, the light shielding member 410 can be implemented to have a quadrangular shape, as shown in FIG. 4, without being limited thereto. For example, the light shielding member 410 can be implemented to have a shape corresponding to the shape of a sub-pixel associated therewith (or the light emission region of the sub-pixel). In another example, the light shielding member 410 can be implemented to have a shape of a periphery (or a boundary) of the associated sub-pixel. For a more concrete example, refer to FIG. 7.

In an embodiment, the third pixel 323 and the fourth pixel 324 can be pixels disposed on the curved line of the display area at positions different from that of the second pixel 320. In this case, as apparent from FIG. 3, the area of each of the third pixel 323 and the fourth pixel 324 included in the non-display area can be different from the area of the second pixel 320 included in the non-display area. In detail, for example, in the case of the second pixel 320, 20% of the total area thereof can be included in the non-display area. In the case of the third pixel 323, 80% of the total area thereof can be included in the non-display area. In the case of the fourth pixel 324, 35% of the total area thereof can be included in the non-display area.

In this case, on each sub-pixel of the second pixel 320, a light shielding member (for example, the light shielding member 410) corresponding to 20% of the area of the sub-pixel can be disposed. On each sub-pixel of the third pixel 323, a light shielding member corresponding to 80% of the area of the sub-pixel can be disposed. On each sub-pixel of the fourth pixel 324, a light shielding member corresponding to 35% of the area of the sub-pixel can be disposed. The light shielding member disposed on each of the second pixel 320, the third pixel 323, and the fourth pixel 324 can be disposed with reference to a center of the sub-pixel, on which the light shielding member is disposed, as shown in FIG. 4, without being limited thereto.

In an embodiment, a touch wiring can be disposed around each sub-pixel. For example, a first touch wiring 421 can be disposed at one side of the third sub-pixel 404 of the second pixel 320, and a second touch wiring 422 can be disposed at the other side of the third sub-pixel 404.

In an embodiment, the first touch wiring 421 can correspond to a touch sensor electrode (or a touch sensor line). The second touch wiring 422 can correspond to a touch bridge electrode (or a touch bridge line). Here, the touch sensor electrode can include an electrode disposed on a first plane, to transmit and receive a touch signal. The touch bridge electrode can include an electrode disposed on a second plane under the first plane and electrically connected to the touch sensor electrode via a contact hole. The touch sensor electrode and the touch bridge electrode can be disposed on a higher plane than a light emission region.

In an embodiment, each of the first touch wiring 421 and the second touch wiring 422 can be connected to a touch sensor, to realize a touch function.

In an embodiment, the second touch wiring 422 can be a wiring disposed on a plane different from that of the first touch wiring 421. For example, the first touch wiring 421 can be disposed on a first plane above the plane on which the light emission region is disposed, and the second touch wiring 422 can be disposed on a second plane between the first plane and the plane on which the light emission region is disposed.

In an embodiment, at least one of the first touch wiring 421 and the second touch wiring 422 can correspond to at least one of various wirings used for sensing of touch input. The various wirings used for sensing of touch input can include, for example, at least one of a Tx wiring for transmitting a signal for sensing of a touch signal, a Tx routing wiring connected to the Tx wiring, an Rx wiring for receiving a signal sensed by a touch sensor, or an Rx routing wiring connected to the Rx wiring. Functions corresponding to the first touch wiring 421 and the second touch wiring 422 can be implemented to correspond to one of the above-described wirings associated with touch input sensing.

The first touch wiring 421 and the second touch wiring 422 can be disposed on the second pixel 320, and can be disposed on a higher plane than a sub-pixel included in the second pixel 320 (for example, the third sub-pixel 404). A light shielding member disposed on the sub-pixel (for example, the light shielding member 410) can be disposed on a plane on which the first touch wiring 421 or the second touch wiring 422 is disposed.

In an embodiment, the light shielding member can be implemented to include a material constituting the first touch wiring 421 or the second touch wiring 422. For example, when the first touch wiring 421 is implemented to include aluminum (Al) and/or titanium (Ti), the light shielding member can also be implemented to include aluminum (Al) and/or titanium (Ti) constituting the first touch wiring 421. Of course, the exemplary embodiments are not limited to the above-described condition and, for example, the first touch wiring 421 and/or the light shielding member can be implemented to include at least one of copper (Cu) or molybdenum (Mo).

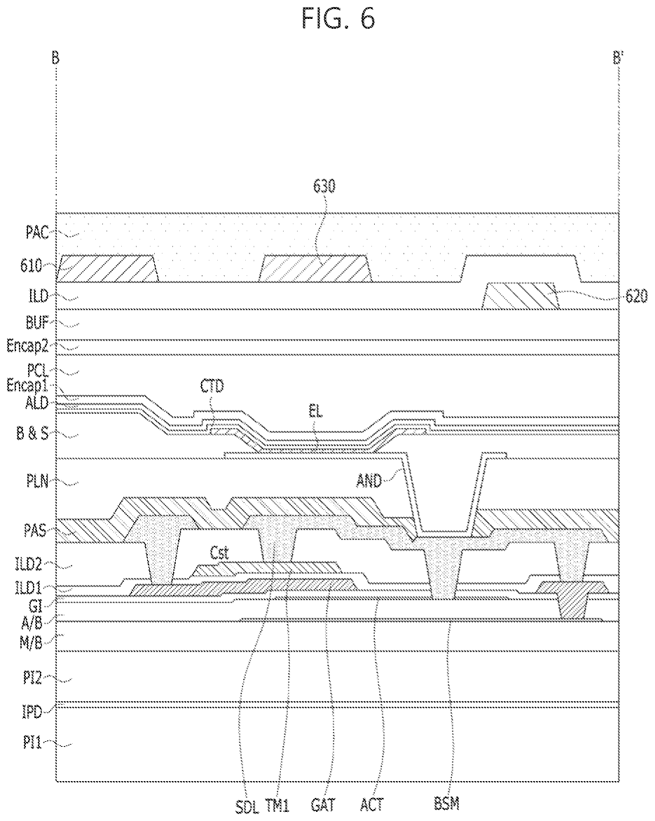

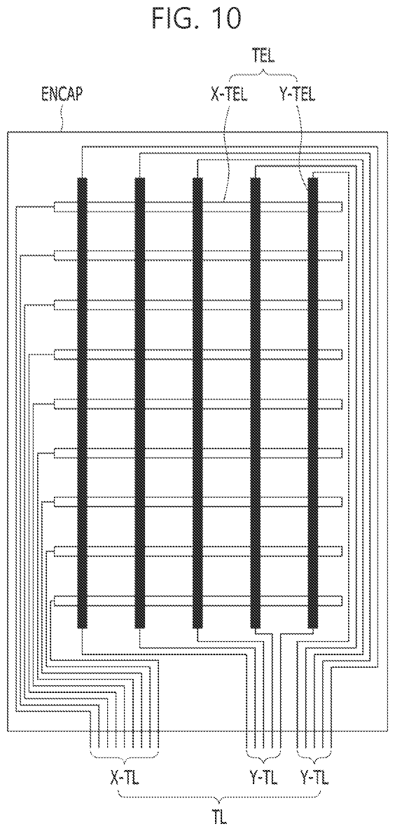

In an embodiment, the first touch wiring 421 and the second touch wiring 422 can be implemented to have a structure in which the first touch wiring 421 and the second touch wiring 422 are disposed on an encapsulation layer. For a more concrete example associated with this structure, refer to FIG. 5 or 6. In addition, for a detailed description as to the structure of the first touch wiring 421 and the second touch wiring 422, refer to FIGS. 10 to 12.

FIGS. 5 and 6 are views explaining cross-sections of a display device according to an exemplary embodiment of the disclosure. In detail, FIG. 5 shows a cross-section of a sub-pixel, on which no light shielding member is disposed, taken along line A-A′ in FIG. 4. FIG. 6 shows a cross-section of a sub-pixel, on which a light shielding member is disposed, taken along line B-B′ in FIG. 4.

Referring to FIG. 5, in a display area of a display device (or a display panel) according to an exemplary embodiment of the disclosure, a substrate PI1 and PI2, a buffer layer M/B and A/B, a metal layer BSM, a transistor (a gate GAT, an active region ACT, and a source/drain SDL), a capacitor Cst (at least one storage electrode TM1 and/or gate GAT and/or an active region ACT and/or the metal layer BSM), a gate insulating layer GI, an insulating layer ILD1 and ILD2, an interlayer insulating layer IPD, a passivation layer PAS, a planarization layer PLN, a light emitting element (an anode AND, a light emitting layer EL, and a cathode CTD), a protective layer ALD, a bank-and-spacer B&S, an encapsulation layer Encap1, PCL and Encap2, a touch buffer BUF, a touch insulating layer ILD, a first touch wiring 510, a second touch wiring 520, and a photoacryl PAC can be disposed.

The buffer layer M/B and A/B can be disposed on the substrate PI1 and PI2. The buffer layer M/B and A/B can perform functions for enhancing bonding force between the substrate PI1 and PI2 and layers formed on the buffer layer M/B and A/B and blocking alkali components or the like leaking from the substrate PI1 and PI2, and other functions. The buffer layer M/B and A/B is not an essential constituent element and, as such, can be omitted based on the kind and material of the substrate PI1 and PI2, the structure and type of the transistor, etc.

The transistor can be disposed on the buffer layer M/B and A/B. The transistor can include the active region ACT, the gate GAT, and the source/drain SDL. The source/drain SDL can represent a source electrode and a drain electrode. Design of the source/drain SDL can be varied in accordance with design of a pixel circuit. For example, a source region and a drain region can be interchanged.

The active region ACT can include a channel region, in which a channel is formed during driving of the transistor, and a source region and a drain region at opposite sides of the channel region. The source region can mean a portion of the active region ACT connected to the source electrode, and the drain region can mean a portion of the active ACT region connected to the drain electrode.

The active region ACT can be constituted by various metal oxides such as indium-gallium-zinc oxide (IGZO) or the like. The active region ACT of the transistor has been described as being formed based on an IGZO layer, assuming that the active region ACT is constituted by IGZO selected from various metal oxides, the exemplary embodiments of the disclosure are not limited thereto. The active region ACT can be formed of metal oxides other than IGZO, such as indium-zinc oxide (IZO), indium-gallium-tin oxide (IGTO), indium-gallium oxide (IGO), or the like. The active region ACT can be formed by depositing a metal oxide on the buffer layer MB and A/B, performing a thermal treatment process for stabilization, and patterning the metal oxide.

The gate insulating layer GI can be disposed on the active region ACT. The gate insulating layer GI can be constituted by a single layer of silicon nitride (SiN_{X}) or silicon oxide (SiO_{X}) or multiple layers thereof. Contact holes can be formed at the gate insulating layer GI in order to connect the source electrode and the drain electrode of the transistor to the source region and the drain region of the active region ACT, respectively.

The gate GAT of the transistor can be disposed on the gate insulating layer GI. The gate GAT can be constituted by a single layer or multiple layers made of one of molybdenum (Mo), copper (Cu), titanium (Ti), aluminum (Al), chromium (Cr), gold (Au), nickel (Ni) and neodymium (Nd) or an alloy thereof. The gate GAT can be formed on the gate insulating layer GI, to overlap with the channel region of the active region ACT of the transistor.

The insulting layer ILD1 and ILD2 can be disposed on the gate insulating layer GI and the gate GAT. The insulating layer ILD1 and ILD2 can be constituted by a single layer of silicon nitride (SiN_{X} or silicon oxide (SiO_{X}) or multiple layers thereof. Contact holes can be formed at the insulating layer ILD1 and ILD2, to expose the source region and the drain region of the active region ACT of the transistor, respectively.

The source/drain SDL of the transistor can be disposed on the insulating layer ILD1 and ILD2. Although the source electrode and the drain electrode have been collectively referred to as the source/drain SDL in the description given with reference to FIG. 5, the exemplary embodiments of the disclosure are not limited thereto. A portion of the source/drain SDL can be referred to as a source electrode, and the remaining portion of the source/drain SDL can be referred to as a drain electrode. The source electrode and the drain electrode of the transistor can be connected to the active region ACT of the transistor through the contact holes formed at the gate insulating layer GI and the insulating layer ILD1 and ILD2. Accordingly, the source electrode of the transistor can be connected to the source region of the active region ACT via corresponding ones of the contact holes formed at the gate insulating layer GI and the insulating layer ILD1 and ILD2. In addition, the drain electrode of the transistor can be connected to the drain region of the active region ACT via corresponding ones of the contact holes formed at the gate insulating layer GI and the insulating layer ILD1 and ILD2.

The passivation layer PAS can be disposed on the source electrode and the drain electrode of the transistor. For example, the passivation layer PAS can be disposed to cover a plurality of transistors. The passivation layer PAS can be constituted by a single layer of silicon nitride (SiN_{X}) or silicon oxide (SiO_{X}) or multiple layers thereof. A contact hole can be formed at the passivation layer PAS, to expose the drain electrode of the transistor.

The planarization layer PLN can be disposed on the passivation layer PAS. Contact holes can be formed at the passivation layer PAS and the planarization layer PLN, to expose the drain electrode. The planarization layer PLN can be an organic material layer for planarizing and protecting an upper portion of the transistor. For example, the planarization layer PLN can be formed of an organic material such as acryl resin, epoxy resin, phenolic resin, polyamide resin, polyimide resin, or the like.

An additional signal wiring can be disposed at the planarization layer PLN.

The light emitting element can be disposed on the planarization layer PLN. The light emitting element can include the anode AND, the cathode CTD, and the light emitting layer EL.

The anode AND can be disposed on the planarization layer PLN. The anode AND can be electrically connected to the source/drain SDL via the contact hole formed at the planarization layer PLN. Accordingly, the anode AND can be electrically connected to the transistor.

The display device according to FIG. 5 is a top emission display device and, as such, the electrode connected to the transistor via the contact hole can correspond to the anode AND. Of course, if necessary, the display device can be implemented to have a bottom emission structure. In this case, the anode AND of FIG. 5 is substituted by a cathode CTD, and the cathode CTD of FIG. 5 can be substituted by an anode AND.

A bank-and-spacer B&S can be disposed on the planarization layer PLN and the anode AND. An opening can be formed at a bank of the bank-and-spacer B&S, to expose the anode AND. The bank can define a light emission region of the display device and, as such, can be referred to as a pixel definition layer. Although the bank is shown in FIG. 5 without being distinguished from a spacer of the bank-and-spacer B&S, the spacer can be disposed on the bank after formation of the bank, if necessary.

The light emitting layer EL can be disposed on the anode AND. The light emitting layer EL can be formed as a hole-related layer, a light emitting layer and an electron-related layer are stacked in this order or in reverse order. In addition, the light emitting layer EL can be provided with first and second light emitting structures facing each other under the condition that a charge generation layer is interposed therebetween. In this case, one light emitting layer of the first and second light emitting structures can generate blue light, and the other light emitting layer of the first and second light emitting structures can generate yellow-green light and, as such, white light can be generated through the first and second light emitting structures. As color light corresponding to each sub-pixel is generated from the light emitting layer EL of the sub-pixel, the display device can realize display of a color image. For example, the light emitting layer EL of the red sub-pixel can generate red light, the light emitting layer EL of the green sub-pixel can generate green light, and the light emitting layer EL of the blue sub-pixel can generate blue light.

If necessary, white light generated in a light emitting layer can be incident on a color filter disposed over the light emitting layer and, as such, display of a color image can be realized.

The cathode CTD can be disposed on the light emitting layer EL. The cathode CTD can be disposed on the light emitting layer EL so that the light emitting layer EL faces the anode AND under the condition that the light emitting layer EL is interposed therebetween.

The protective layer ALD can be formed through atomic layer deposition, and can prevent damage to the light emitting element caused by outgas from an organic encapsulation layer during execution of a process. The lifespan of the display panel (or the display device) can be lengthened by virtue of the protective layer ALD

The encapsulation layer can be disposed on the light emitting element. The encapsulation layer can suppress moisture penetration into the cathode CII). The encapsulation layer can include a first inorganic encapsulation layer Encap1, an organic encapsulation layer PCL, and a second inorganic encapsulation layer Encap2. The first inorganic encapsulation layer Encap1 of the encapsulation layer can be disposed on the cathode CTD. The organic encapsulation layer PCL can be disposed on the first inorganic encapsulation layer Encap1. In addition, the second inorganic encapsulation layer Encap2 can be disposed on the organic encapsulation layer PCL. The first inorganic encapsulation layer Encap1 and the second inorganic encapsulation layer Encap2 of the encapsulation layer can be formed of an inorganic material such as silicon nitride (SiN_{X}), silicon oxide (SiO_{X}) or the like. The organic encapsulation layer PCL of the encapsulation layer can be formed of an organic material such as acryl resin, epoxy resin, phenolic resin, polyamide resin, polyimide resin, or the like.

The touch buffer BUF, the touch insulating layer ILD, and the touch wirings 510 and 520 can be disposed on the second inorganic encapsulation layer Encap2 of the encapsulation layer. The touch insulating layer ILD can be formed of an inorganic material such as silicon nitride (SiN_{X}), silicon oxide (SiO_{X}) or the like. The first touch wiring 510 can be disposed on the touch insulating layer ILD, and the second touch wiring 520 can be disposed on the touch buffer BUF. The photoacryl PAC can be disposed on the touch wirings 510 and 520 and the touch insulating layer ILD.

The case of FIG. 5 is associated with a pixel from which a light shielding member is omitted and, as such, disposition of a separate light shielding member can be unnecessary. For an example in which a light shielding member is disposed, refer to FIG. 6. In the following description given with reference to FIG. 6, contents overlapping with those of FIG. 5 will be omitted.

Referring to FIG. 6, a light shielding member 630 can be disposed on a plane on which a first touch wiring 610 (performing the same function as the first touch wiring 510 of FIG. 5) is disposed. For example, the light shielding member 630 can be disposed on the same plane as the first touch wiring 610. For example, the light shielding member 630 can be disposed on the touch insulating layer ILD.

In an embodiment, the light shielding member 630 can be constituted by the same material as the first touch wiring 610. In accordance with an embodiment, the light shielding member 630 can be constituted by the same material as a second touch wiring 620 (performing the same function as the second touch wiring 520 of FIG. 5).

In an embodiment, the light shielding member 630 can be disposed on the same plane as the second touch wiring 620. For example, the light shielding member 630 can be disposed on the touch buffer BUF. In this case, the light shielding member 630 can be constituted by the same material as the second touch wiring 620, without being limited thereto.

The area of the light shielding member 630 can be determined in accordance with a rate of an area of a pixel, on which the light shielding member 630 is disposed, included in the non-display area with respect to a total area of the pixel. For example, when 20% of the pixel, on which the light shielding member 630 is disposed, is included in the non-display area, the light shielding member 630 can have an area corresponding to 20% of the area of a light emission region of the pixel. In this case, the light shielding member 630 can be disposed on the light emission region and, as such, can shield light generated from the light emitting element by 20%.

Here, the light emission region can include a region in which a bank and a spacer are not disposed, for example, a region in which a bank and a spacer are opened. If necessary, the light emission region can correspond to a region in which the light emitting layer EL is disposed.

In an embodiment, the thickness of the light shielding member 630 can correspond to the thickness of the first touch wiring 610 or the second touch wiring 620. For example, the thickness of the light shielding member 630 can be equal to the thickness of the first touch wiring 610. Of course, the exemplary embodiments of the disclosure are not limited to the above-described condition, and the light shielding member 630 can be formed to have a thickness different from that of the first touch wiring 610 or the second touch wiring 620.

In an embodiment, the cross-section of the light shielding member 630 can correspond to the cross-section of the first touch wiring 610 or the second touch wiring 620. For example, the light shielding member 630 can have the same cross-sectional shape as the first touch wiring 610. Of course, the exemplary embodiments of the disclosure are not limited to the above-described condition, and the light shielding member 630 can be formed to have a cross-sectional shape different from that of the first touch wiring 610 or the second touch wiring 620.

It is to be noted that, although the above embodiments of the present disclosure have described the light shielding member as being disposed over the second pixel, embodiments of the present disclosure are not limited thereto. For example, in case that display device is implemented to have a bottom emission structure, the light shielding member is disposed under the second pixel, so as to shield the light emitted from the light emitting element of the second pixel. In this case, the light shielding member can be formed of the same material as the source/drain SDL or the gate GAT, rather than the first touch wiring 610 or the second touch wiring 620.

FIG. 7 is a view explaining a pixel of a display device according to another exemplary embodiment of the disclosure.

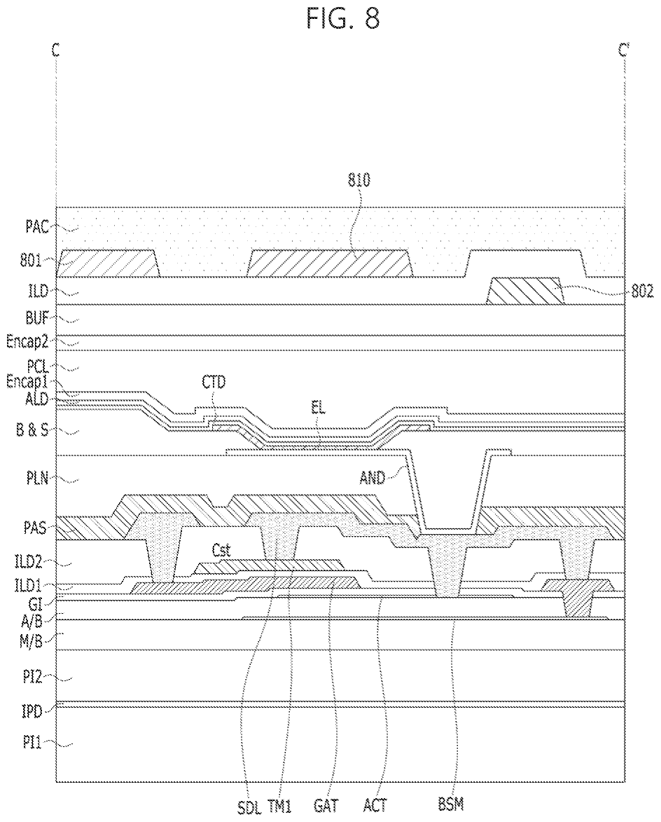

In FIG. 7, reference numeral “710” represents the case in which a light shielding member 701 has a shape corresponding to a shape of a sub-pixel 703. In accordance with the case represented by reference numeral “710”, the light shielding member 701 can be disposed with reference to a center of the sub-pixel 703, and the shape of the light shielding member 701 can correspond to the shape of the sub-pixel 703. For a cross-section C-C′ taken when an embodiment is implemented as in the case represented by reference numeral “710”, refer to FIG. 8.

Still in FIG. 7, light generated in the sub-pixel 703 can pass through a region of the sub-pixel 703 in which the light shielding member 701 is not disposed, for example, a light transmissive region 705. Light can be shielded in a region in which the light shielding member 701 is disposed. Accordingly, light generated in the sub-pixel 703 can be emitted corresponding to a ratio of the area of the light transmissive region 705 to the area of the sub-pixel 703.

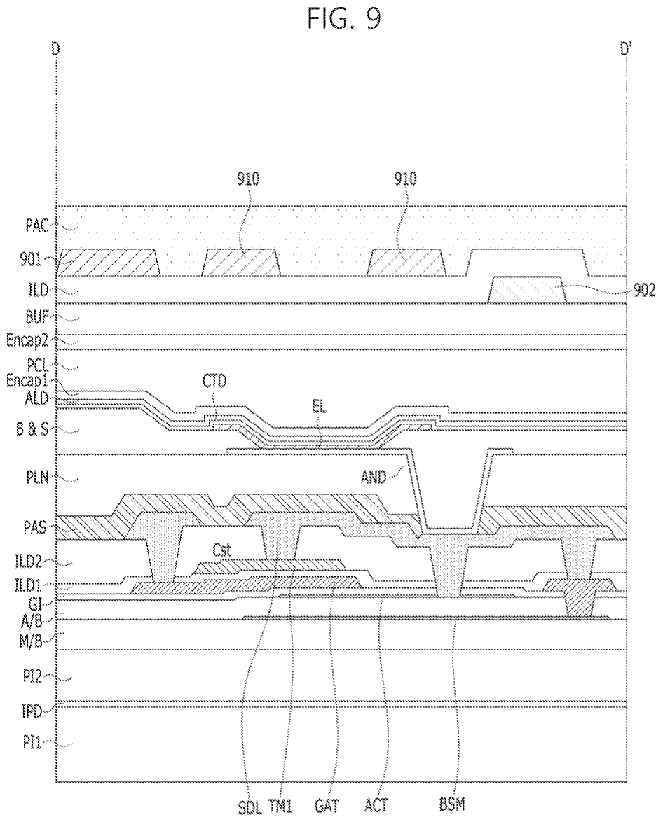

Further, in FIG. 7, reference numeral “720” represents the case in which a light shielding member 711 has a shape corresponding to a shape of a boundary of a sub-pixel 713. In accordance with the case represented by reference numeral “720”, the light shielding member 711 can be disposed along the boundary (or a periphery) of the sub-pixel 713. In this case, the light shielding member 711 is disposed at the boundary of the sub-pixel 713, and a light transmissive region 715 can be disposed at a center of the sub-pixel 713. For a cross-section D-D′ taken when an embodiment is implemented as in the case represented by reference numeral “720”, refer to FIG. 9.

Still in FIG. 7, light generated in the sub-pixel 713 can pass through a region of the sub-pixel 713 in which the light shielding member 711 is not disposed, for example, the light transmissive region 715. Light can be shielded in a region in which the light shielding member 711 is disposed. Accordingly, light generated in the sub-pixel 713 can be emitted corresponding to a ratio of the area of the light transmissive region 715 to the area of the sub-pixel 713.

FIGS. 8 and 9 are views explaining cross-sections of display devices, taken respectively along lines C-C′ and D-D′ in FIG. 7, according to different exemplary embodiments of the disclosure, respectively. In the following description given in conjunction with FIGS. 8 and 9, contents overlapping with those of FIGS. 5 and 6 can be omitted.

Particularly, FIG. 8 shows a cross-section C-C′ of a sub-pixel at which a light shielding member according to the case represented by reference numeral “710” is disposed. Referring to FIG. 8, a light shielding member 810 can be disposed on the same plane as a first touch wiring 801. The light shielding member 810 can be disposed on a light emitting element including a cathode CTD, and anode AND and a light emitting layer EL and, as such can shield at least a portion of light generated from the light emitting element.

Light shielded by the light shielding member 810 can be associated with a ratio of an area of the light shielding member 810 to the area of the light emitting element. For example, when the rate of the area of the light shielding member 810 with respect to the area of the light emitting element is 80%, light shielded by the light shielding member 810 can correspond to 80% of the emission amount of light emitted from the light emitting element.

Although the light shielding member 810 is illustratively shown in FIG. 8 as being disposed on the same plane as the first touch wiring 801, the exemplary embodiments of the disclosure are not limited thereto. In accordance with an embodiment, the light shielding member 810 can be disposed on the same plane as the second touch wiring 802. In this case, the light shielding member 810 can be constituted by the same material as the second touch wiring 802.

Since the plane of the light shielding member 810 of FIG. 8 corresponds to the shape of the sub-pixel, the plane of the light shielding member 810 can have a diamond shape, as shown in FIG. 7. FIG. 8 shows a cross-section crossing a central portion of the diamond shape and, as such, can be shown as being wider than cross-sections of the diamond shape at other positions. When the cross-section C-C′ is shifted upwards or downwards on a y-axis, the width of the cross-section of the light shielding member 810 can be reduced.

FIG. 9 shows a cross-section D-D′ of a sub-pixel at which a light shielding member according to the case represented by reference numeral “720” is disposed. Referring to FIG. 9, a light shielding member 910 can be disposed on the same plane as a first touch wiring 901. The light shielding member 910 can be disposed on a light emitting element including a cathode CTD, an anode AND and a light emitting layer EL and, as such can shield at least a portion of light generated from the light emitting element.

The light shielding member 910 of FIG. 9 can be formed on a sub-pixel along a boundary of the sub-pixel. Accordingly, the light shielding member 910 may not be disposed at a central portion of the sub-pixel, but can be disposed at a peripheral portion of the sub-pixel.

In an embodiment, each of FIGS. 5, 6, 8 and 9 can show a cross-section of one of a plurality of sub-pixels constituting one pixel. As such, in accordance with embodiments, a light shielding member can be disposed at each of the sub-pixels while having a shape corresponding to at least one of shapes shown in FIGS. 5, 6, 8 and 9. For example, when a pixel includes a first sub-pixel and a second sub-pixel, a light shielding member according to FIG. 5 can be disposed at the first sub-pixel, and a light shielding member according to FIG. 6 can be disposed at the second sub-pixel.

FIGS. 10 to 13 are views explaining a structure for realizing a touch function of a display device according to an exemplary embodiment of the disclosure.

Particularly, FIG. 10 is a diagram briefly showing a touch electrode structure for touch sensing based on mutual capacitance in a display device according to an exemplary embodiment of the disclosure.

Referring to FIG. 10, in a display device according to an exemplary embodiment of the disclosure (for example, the display device 100 of FIG. 1), a touch electrode structure thereof for touch sensing based on mutual capacitance can include a plurality of X-touch electrode lines X-TEL (or X-touch wirings) and a plurality of Y-touch electrode lines Y-TEL (or Y-touch wirings). In this case, the plurality of X-touch electrode lines X-TEL and the plurality of Y-touch electrode lines Y-TEL are disposed on an encapsulation layer ENCAP.

Each of the plurality of X-touch electrode lines X-TEL can be disposed to extend in a first direction, whereas each of the plurality of Y-touch electrode lines Y-TEL can be disposed to extend in a second direction different from the first direction.

In the disclosure, the first direction and the second direction can be directions relatively different from each other and, for example, the first direction can be an x-axis direction, and the second direction can be a y-axis direction. Conversely, the first direction can be the y-axis direction, and the second direction can be the x-axis direction. In addition, the first direction and the second direction can perpendicularly intersect each other or may not perpendicularly intersect each other. In addition, in the disclosure, a row and a column are relative to each other and, as such, can be interchanged in accordance with a viewing direction.

Each of the plurality of X-touch electrode lines X-TEL can be constituted by several X-touch electrodes that are electrically interconnected Each of the plurality of Y-touch electrode lines Y-TEL, can be constituted by several Y-touch electrodes that are electrically interconnected.

Here, the plurality of X-touch electrodes and the plurality of Y-touch electrodes are electrodes included in a plurality of touch electrodes TE while having functions distinguished from each other, respectively.

For example, the plurality of X-touch electrodes constituting each of the plurality of X-touch electrode lines X-TEL can be touch driving electrodes, whereas the plurality of Y-touch electrodes constituting each of the plurality of Y-touch electrode lines Y-TEL can be touch sensing electrodes. In this case, each of the plurality of X-touch electrode lines X-TEL corresponds to a touch driving electrode line, whereas each of the plurality of Y-touch electrode lines Y-TEL corresponds to a touch sensing electrode line.

Conversely, the plurality of X-touch electrodes constituting each of the plurality, of X-touch electrode lines X-TEL can be touch sensing electrodes, whereas the plurality of Y-touch electrodes constituting each of the plurality of Y-touch electrode lines Y-TEL can be touch driving electrodes. In this case, each of the plurality of X-touch electrode lines X-TEL corresponds to a touch sensing electrode line, whereas each of the plurality of Y-touch electrode lines Y-TEL corresponds to a touch driving electrode line.

The touch electrode structure for touch sensing can include a plurality of touch lines TL in addition to the plurality of X-touch electrode lines X-TEL, and the plurality of Y-touch electrode lines Y-TEL.

The plurality of touch lines TL can include one or more X-touch lines X-TL respectively connected to the plurality of X-touch electrode lines X-TEL, and one or more Y-touch lines Y-TL respectively connected to the plurality of Y-touch electrode lines Y-TEL.

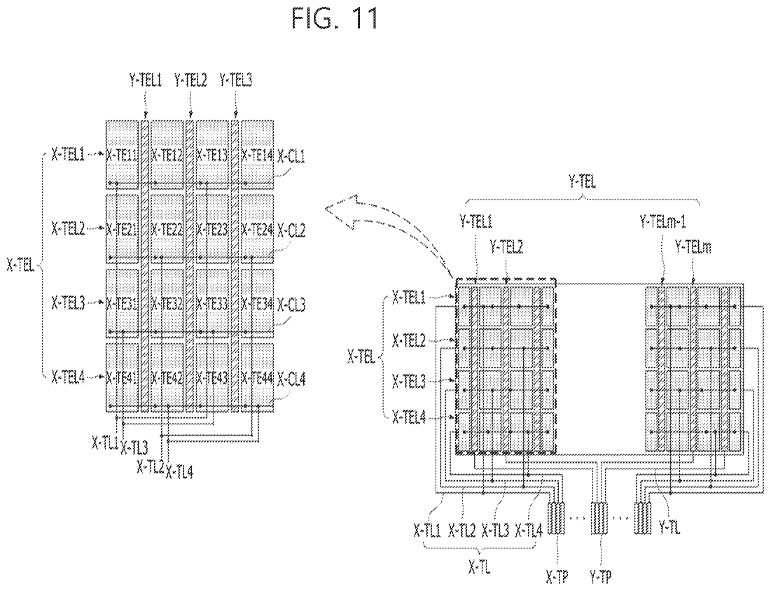

FIG. 11 is a view illustratively showing a display panel having a multi-feeding structure, in which a touch signal is simultaneously applied to a plurality of touch electrodes disposed on the same line, in a touch display device according to an exemplary embodiment of the disclosure.

Referring to FIG. 11, in a touch display device according to an exemplary embodiment of the disclosure (or the display device 100 of FIG. 1), a touch line can be configured to have a multi-feeding structure so that a touch signal is simultaneously applied to a plurality of touch electrodes constituting the same touch electrode line TEL, for reduction of temporal delay of the touch signal.

In this case, when a plurality of X-touch electrodes arranged in an x-axis direction constitute one X-touch electrode line X-TEL, the plurality of X-touch electrodes constituting one X-touch electrode line X-TEL can be interconnected by an X-touch electrode connection line X-CL, and a plurality of X-touch electrodes disposed on the same line can be interconnected by the same X-touch line X-TL, in order to enable a touch signal to be simultaneously applied to the plurality of X-touch electrodes constituting one X-touch electrode line X-TEL.

Alternatively, when a plurality of Y-touch electrodes arranged in a y-axis direction constitute one Y-touch electrode line Y-TEL, a plurality of Y-touch electrodes disposed on the same line can be interconnected by the same Y-touch line Y-TL, in order to enable a touch signal to be simultaneously applied to the plurality of Y-touch electrodes constituting one Y-touch electrode line Y-TEL.

Here, the case in which each x-axis directional X-touch electrode line X-TEL is constituted by a plurality of X-touch electrodes, and each y-axis directional Y-touch electrode line Y-TEL is constituted by one Y-touch electrode is illustratively shown. In this case, accordingly, a plurality of X-touch electrodes arranged in the same row in the x-axis direction carp be interconnected by the same X-touch line X-TL.

For example, a first-row X-touch electrode line X-TEL1 is constituted by a plurality of X-touch electrodes disposed in a first row, and the plurality of X-touch electrodes disposed in the first row is electrically connected to a first X-touch line X-TL1 having a branched structure and, as such, a first touch signal can be simultaneously transmitted to the plurality of X-touch electrodes.

As a touch signal is simultaneously applied to a plurality of X-touch electrodes disposed in the x-axis direction, as described above, delay of the touch signal for the plurality of X-touch electrodes can be reduced and, as such, the touch performance of the entire screen of the display panel can be improved and uniformly provided.

For example, when each of the plurality of X-touch electrodes disposed in the x-axis direction is a touch driving electrode, the plurality of X-touch electrodes constituting one X-touch electrode line X-TEL can be electrically interconnected by the same X-touch line X-TL and, as such, the same touch driving signal can be applied to the plurality of X-touch electrodes at the same timing.

A plurality of X-touch electrode lines X-TEL1, . . . , and X-TELn can be electrically connected to corresponding ones of X-touch pads X-TP via X-touch lines X-TL1, . . . , and X-TLn, respectively, where n can be a positive number such as an integer greater than 1. For example, a plurality of X-touch electrodes included in a first X-touch electrode line X-TEL1 can be electrically connected to the corresponding X-touch pad X-TP via a first X-touch line X-TL1.

On the other hand, since Y-touch electrode lines Y-TEL1, . . . , and Y-TELm are each constituted by one Y-touch electrode, each of the Y-touch electrode lines Y-TEL1, . . . , and Y-TELm can be electrically connected to a corresponding Y-touch pad Y-TP via one Y-touch line Y-TL, where m can be a positive number such as an integer greater than 1.

In this case, the structure in which one touch line is branched in order to connect the touch line to a plurality of touch electrodes constituting the same touch electrode line TEL can be diversely varied.

Meanwhile, the X-touch line X-TL connected to the X-touch electrodes X-TE disposed in each row can be alternately arranged on a multi-line basis.

In the touch display device according to the exemplary embodiment of the disclosure, X-touch lines X-TL or Y-touch lines Y-TL are alternately arranged and, as such, it can be possible to reduce the number of touch lines TL and to secure a desired area of a touch electrode TE.

The following description will be given in conjunction with, for example, a mutual capacitance-based touch sensing structure in which touch electrodes TE11 to TE44 are arranged in a 4×4 matrix.

In the mutual capacitance-based touch sensing structure, X-touch electrode lines X-TEL and Y-touch electrode lines Y-TEL can be disposed to intersect each other.

For example, a first X-touch electrode line X-TEL1 can be constituted by a first-row first-column X-touch electrode X-TE11, a first-row second-column X-touch electrode X-TE12, a first-row third-column X-touch electrode X-TE13, and a first-row fourth-column X-touch electrode X-TE14.

In this case, X-touch electrodes X-TE11, X-TE12, X-TE13 and X-TE14 disposed in the first row can be interconnected in the x-axis direction by a first X-touch electrode connection line X-CL1. Accordingly, a touch signal transmitted through a part of the X-touch electrodes X-TE11, X-TE12, X-TE13 and X-TE14 disposed in the first row can be transmitted to all of the X-touch electrodes X-TEI 1, X-TE12, X-TE13 and X-TE14 disposed in the first row by the first X-touch electrode connection line X-CL1.

In addition, X-touch electrodes X-TE21, X-TE22, X-TE23 and, X-TE24 disposed in the second row can be interconnected in the x-axis direction by a second X-touch electrode connection line X-CL2. Accordingly, a touch signal transmitted through a part of the X-touch electrodes X-TE21, X-TE22, X-TE23 and X-TE24 disposed in the second row can be transmitted to all of the X-touch electrodes X-TE21, X-TE22, X-TE23 and X-TE24 disposed in the second row by the second X-touch electrode connection line X-CL2.

In this case, X-touch lines X-TL1, X-TL2, X-TL3, and X-TL4 extending in a y-axis direction can be alternately arranged and, as such, can be connected to the X-touch electrodes X-TE11 to X-TE44.

For example, among the X-touch electrodes X-TE11, X-TE21, X-TE31 and XTE41 disposed in the first column, the first-row first-column X-touch electrode X-TE11 is connected to the first X-touch line X-TL1, and the third-row first-column X-touch electrode X-TE31 is connected to the third X-touch line X-TL3.

On the other hand, the second-row first-column X-touch electrode X-TE21 and the fourth-row first-column X-touch electrode X-TE41 are not connected to any X-touch line X-TL.

However, since the first-row X-touch electrodes X-TE11, X-TE12, X-TE13 and XTE14 are connected in the x-axis direction by the first-row X-touch electrode connection line X-CL1, a touch signal transmitted via the first X-touch line X-TL1 can be transmitted to all of the first-row X-touch electrodes X-TE11, X-TE12, X-TE13 and XTE14.

Similarly, the third-row X-touch electrodes X-TE31, X-TE32, X-TE33 and XTE34 are connected in the x-axis direction by the third-row X-touch electrode connection line X-CL3 and, as such, a touch signal transmitted via the third X-touch line X-TL3 can be transmitted to all of the third-row X-touch electrodes X-TE31, X-TE32, X-TE33 and XTE34.

Thus, it can be possible to transmit a touch signal by disposing only two X-touch lines X-TL1 and X-TL3 in an area where the four X-touch electrodes X-TE11, X-TE21, X-TE31 and XTE41 in the first column are disposed and, as such, to reduce the number of touch lines TL.

In this case, among the X-touch electrodes X-TE12, X-TE22, X-TE32 and XTE42 disposed in the second column, the second-row second-column X-touch electrode X-TE22 is connected to the second X-touch line X-TL2, and the fourth-row second-column X-touch electrode X-TE42 is connected to the fourth X-touch line X-TL4. On the other hand, the first-row second-column X-touch electrode X-TE12 and the third-row second-column X-touch electrode X-TE32 are not connected to any X-touch line X-TL.

Accordingly, connection points of the X-touch lines X-TL1 and X-TL3 connected to the first column X-touch electrodes corresponding to a left area with reference to the first Y-touch electrode line Y-TEL1 can be disposed to be misaligned from connection points of the X-touch lines X-TL2 and X-TL4 connected to the second column X-touch electrodes corresponding to a right area with reference to the first Y-touch electrode line Y-TEL1.

As a result, it can be possible to transmit a touch signal by disposing only two X-touch lines x-TL2 and X-TL4 in an area where the four X-touch electrodes X-TE12, X-TE22, X-TE32 and XTE42 in the second column are disposed and, as such, to reduce the number of touch lines TL.

Meanwhile, for X-touch electrodes X-TE13, X-TE23, X-TE33 and X-TE43 disposed in the third column, X-touch lines X-TL can be connected thereto n the same manner as the first column. For example, the first-row third-column X-touch electrode X-TE13 is connected to the first X-touch line X-TL1, and the third-row third-column X-touch electrode X-TE33 is connected to the third X-touch line X-TL3. On the other hand, the second-row third-column X-touch electrode X-TE23 and the fourth-row third-column X-touch electrode X-TE43 are not connected to any X-touch line X-TL.

Similarly, for X-touch electrodes X-TE14, X-TE24, X-TE34 and X-TE44 disposed in the fourth column, X-touch lines X-TL can be connected thereto in the same manner as the second column. For example, the second-row fourth-column X-touch electrode X-TE24 is connected to the second X-touch line X-TL2, and the fourth-row fourth-column X-touch electrode X-TE44 is connected to the fourth X-touch line X-TL4. On the other hand, the first-row fourth-column X-touch electrode X-TE14 and the third-row fourth-column X-touch electrode X-TE34 are not connected to any X-touch line X-TL.

Thus, it can be possible to reduce the number of touch lines TL and to secure a desired area of the touch electrode TE through a multi-feeding structure in which the touch lines TL are alternately arranged, and a touch signal is simultaneously applied to X-touch electrodes X-TE disposed in the same row. As a result, an enhancement in touch sensing performance can be achieved.

Although the multi-feeding structure, in which touch lines TL are alternately arranged on a two-line basis, and a touch signal is simultaneously applied to X-touch electrodes X-TE disposed in the same row, has been illustratively described in the above description, it can be possible to implement a multi-feeding structure in which touch lines IL are alternately arranged on an N-line basis (N being a natural number equal to or greater than 2), and a touch signal is simultaneously applied to X-touch electrodes X-TE disposed in the same row.

Meanwhile, in the touch display device according to the exemplary embodiment of the disclosure, the X-touch electrodes X-TE can have the same shape. However, a part of the X-touch electrodes X-TE can have a shape different from that of the remaining part of the X-touch electrodes X-TE.

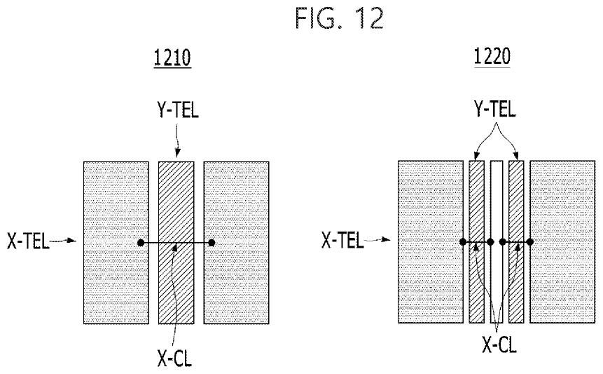

FIG. 12 is a view illustratively showing various structures of a touch electrode line (or a touch wiring) in a touch display device according to an exemplary embodiment of the disclosure.

Referring to FIG. 12, a display device according to an exemplary embodiment of the disclosure (for example, the display device 100 of FIG. 1) can be constituted by touch electrode lines X-TEL and Y-TEL having various structures.

For example, in the touch display device according to the exemplary embodiment of the disclosure, as represented by reference numeral “1210”, an X-touch electrode line X-TEL can be constituted by X-touch electrodes X-TE having the same shape while being disposed at opposite sides in an x-axis direction with reference to a Y-touch electrode line Y-TEL having a single bar structure extending in a y-axis direction.

Alternatively, as represented by reference numeral “1220”, a Y-touch electrode line Y-TEL constituted by two bars, under the condition that an X-touch electrode line having a thin structure is interposed between the two bars, can be formed to have a split structure, and an X-touch electrode line X-TEL can be constituted by X-touch electrodes X-TE having the same shape while being disposed at opposite sides in the x-axis direction with reference to the Y-touch electrode line Y-TEL constituted by the double-bar structure.

In either case, portions of the X-touch electrode line X-TEL separated by the Y-touch electrode line Y-TEL can be interconnected via an X-touch electrode connection line X-CL.

Meanwhile, the area of the X-touch electrode line X-TEL, to which a touch driving signal is applied, and the area of the Y-touch electrode line Y-TEL, to which a touch sensing signal is transmitted, can be equal to or different from each other.

For example, when it is desired to relatively reduce parasitic capacitance caused by the Y-touch electrode line Y-TEL, to which a touch sensing signal is transmitted, the Y-touch electrode line Y-TEL can be formed to have a smaller area than the X-touch electrode line X-TEL. In this case, the area of the X-touch electrode line X-TEL, to which a touch driving signal is applied, and the area of the Y-touch electrode line Y-TEL, to which a touch sensing signal is transmitted, can be determined to have a ratio of 5:1 to 2:1. For example, the area of the X-touch electrode line X-TEL and the area of the Y-touch electrode line Y-TEL can be determined to have a ratio of 4:1.

Structures of the touch electrode lines X-TEL and Y-TEL as described above can be diversely varied in accordance with the size or application of the display device 100.

Meanwhile, an X-touch line X-TL electrically connected to the X-touch electrode line X-TEL can be formed at a position spaced apart from the Y-touch electrode line Y-TEL by a predetermined distance.

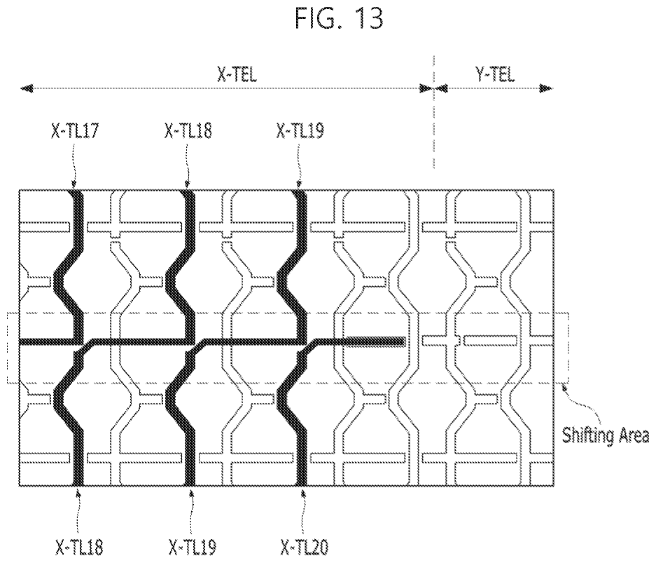

FIG. 13 is a view illustratively showing a touch line in a shifting area in the case in which a touch electrode line is constituted by a mesh type touch electrode metal in a display device according to an exemplary embodiment of the disclosure.

Referring to FIG. 13, in a display device according to an exemplary embodiment of the disclosure (for example, the display device 100 of FIG. 1), an X-touch electrode line X-TEL, to which a touch driving signal is applied, and a Y-touch electrode line Y-TEL, to which a touch sensing signal is transmitted, can be constituted by a mesh type touch electrode metal having an opening.

In this case, each of the touch electrode lines X-TEL and Y-TEL can extend to have repeated structures each having an opening at a central portion thereof and a touch electrode metal surrounding the opening. Here, the case in which the touch electrode metal surrounding the opening has an octagonal shape is illustratively shown.

Further, X-touch lines X-TL, which apply a touch driving signal, can extend along an octagonal touch electrode metal constituting an X-touch electrode line X-TEL, and a designated one of the X-touch lines X-TL can be electrically connected to a X-touch electrode line X-TEL corresponding thereto via a touch contact hole TCH at a position where the X-touch line X-TL is spaced apart from a Y-touch electrode line Y-TEL by a predetermined distance D.

Meanwhile, the touch electrode lines X-TEL and Y-TEL can be constituted by a transparent electrode or can include a transparent electrode, for desired luminous efficiency of sub-pixels SP.

The display device can be applicable to a mobile appliance such as a smartphone or a tablet computer and a display for an automobile. In this case, the display device 100 can use an antenna in order to communicate with other appliances.

A display device, which uses an antenna, can exhibit degradation of a transmission/reception performance for a radio signal and touch sensing performance due to electromagnetic interference thereof with a touch driving signal transmitted by a touch electrode line in a procedure of transmitting and receiving a radio signal of a high-frequency band.

In order to address this problem, in the display device 100 according to the exemplary embodiment of the disclosure, a pseudo touch electrode line capable of offsetting electromagnetic interference between a radio signal and a touch driving signal can be disposed in a non-display area.

As apparent from the above description, a display panel and a display device including such display panel according to the exemplary embodiments of the disclosure can achieve an enhancement in display quality by disposing a light shielding member on a pixel disposed at a curved line portion of a display area, thereby controlling a light emission amount of the pixel.

Further, the light shielding member can be disposed over the second pixel. The entirety of the first pixel can be included in the display area, and the second pixel is disposed to be overlapped with the curved line of the display area.

The foregoing descriptions and the accompanying drawings have been presented in order to illustratively explain technical ideas of the present invention. A person skilled in the art to which the present invention pertains can appreciate that diverse modifications and variations obtained by combining, dividing, substituting for, or changing constituent elements can be possible without changing essential characteristics of the present invention. Therefore, the foregoing embodiments disclosed herein shall be interpreted as illustrative only but not as limitative of the principle and scope of the present invention. It should be understood that the scope of the present invention shall be defined by the appended claims and all equivalents thereto fall within the scope of the present invention.

What is claimed is:

1. A display panel comprising:
a display area shaped into a curved line at at least a portion thereof;
a non-display area adjacent to the display area:
a first pixel included in the display area;
a second pixel disposed at a position corresponding to the curved line of the display area; and
a light shielding member disposed to be overlapped with the second pixel, and disposed to correspond to the position of the second pixel.

2. The display panel according to claim 1, wherein:
a first portion of the second pixel is included in the display area;
a second portion of the second pixel is included in the non-display area;
an area of the first portion and an area of the second portion depend on the position of the second pixel; and
a size of the light shielding member is associated with the area of the second portion.

3. The display panel according to claim 2, wherein:
the second pixel comprises a light emission region; and
the light shielding member is disposed on at least a portion of the light emission region.

4. The display panel according to claim 3, wherein a ratio of an area of the light shielding member to an area of the light emission region corresponds to a ratio of the area of the second portion to an area of the second pixel.

5. The display panel according to claim 1, wherein the light shielding member has a shape corresponding to a shape of the second pixel, a quadrangular shape, or a shape of a periphery of the second pixel.

6. The display panel according to claim 1, wherein the display area has a shape corresponding to an oval shape or a circular shape.

7. The display panel according to claim 1, further comprising:
at least one of a first touch wiring disposed on a first plane above a plane on which the second pixel is disposed, and a second touch wiring disposed on a second plane between the first plane and the plane on which the second pixel is disposed,
wherein a constituent material of the light shielding member is a constituent material of at least one of the first touch wiring and the second touch wiring.

8. The display panel according to claim 7, wherein the constituent material of the light shielding member is the constituent material of the first touch wiring when the plane, in which the light shielding member is disposed, corresponds to the first plane.

9. The display panel according to claim 7, wherein the constituent material of the light shielding member is the constituent material of the second touch wiring when the plane, in which the light shielding member is disposed, corresponds to the second plane.

10. The display panel according to claim 7, wherein:
the first touch wiring corresponds to a touch sensor electrode; and
the second touch wiring corresponds to a touch bridge electrode.

11. A display device comprising:
a display panel comprising a display area having a curved line at at least a portion thereof, and a non-display area adjacent to the display area; and
a driving circuit configured to drive the display panel,
wherein the display panel comprises:
a first pixel included in the display area; and
a second pixel disposed at a position corresponding to the curved line of the display area, and
wherein a light shielding member is disposed to be overlapped with the second pixel, and disposed to correspond to the position of the second pixel.

12. The display device according to claim 11, wherein:
a first portion of the second pixel is included in the display area;
a second portion of the second pixel is included in the non-display area;
an area of the first portion and an area of the second portion depend on the position of the second pixel; and
a size of the light shielding member is associated with the area of the second portion.

13. The display device according to claim 12, wherein:
the second pixel comprises a light emission region; and
the light shielding member is disposed on at least a portion of the light emission region.

14. The display device according to claim 13, wherein a ratio of an area of the light shielding member to an area of the light emission region corresponds to a ratio of the area of the second portion to an area of the second pixel.

15. The display device according to claim 11, wherein the light shielding member has a shape corresponding to a shape of the second pixel, a quadrangular shape, or a shape of a periphery of the second pixel.

16. The display device according to claim 11, wherein the display area has a shape corresponding to an oval shape or a circular shape.

17. The display device according to claim 11, further comprising:
a first touch wiring disposed on a first plane above a plane on which the second pixel is disposed; and/or
a second touch wiring disposed on a second plane between the first plane and the plane on which the second pixel is disposed,
wherein a constituent material of the light shielding member is a constituent material of at least one of the first touch wiring and the second touch wiring.

18. The display device according to claim 17, wherein the constituent material of the light shielding member is the constituent material of the first touch wiring when the plane, in which the light shielding member is disposed, corresponds to the first plane.

19. The display device according to claim 17, wherein the constituent material of the light shielding member is the constituent material of the second touch wiring when the plane, in which the light shielding member is disposed, corresponds to the second plane.

20. The display device according to claim 17, wherein:
the first touch wiring corresponds to a touch sensor electrode; and
the second touch wiring corresponds to a touch bridge electrode.
